(19) United States
(12) Patent Application Publication
(10) Pub. No.: US 2025/0294689 A1
(43) Pub. Date: Sep. 18, 2025

(54) DISPLAY DEVICE

(71) Applicant: Shenzhen China Star Optoelectronics Semiconductor Display Technology Co., Ltd., Shenzhen (CN)

(72) Inventor: Rong XIA, Shenzhen (CN)

(73) Assignee: Shenzhen China Star Optoelectronics Semiconductor Display Technology Co., Ltd., Shenzhen (CN)

(21) Appl. No.: 18/679,245

(22) Filed: May 30, 2024

(30) Foreign Application Priority Data
Mar. 18, 2024 (CN) 202410313332.9

(51) Int. Cl. H05K 5/02

(52) U.S. Cl. CPC H05K 5/0217

(57) ABSTRACT

The present invention discloses a display device. The display device includes a casing, a first winding assembly, a lifting assembly, a transmission assembly, and a display screen disposed in an accommodation chamber. The transmission assembly includes a fastening member at least partially disposed in the accommodation chamber. The lifting assembly is located between a first end of the display screen and a second end of the display screen. The display screen, under a first state, is received in the accommodation chamber. The display screen, under a second state, is located partially outside the accommodation chamber. The transmission assembly controls the lifting assembly to move along a first direction relative to the casing and the first winding assembly to rotate relative to the casing along a second direction to drive the display screen to move relative to the casing along the first direction.

### CROSS REFERENCE TO RELATED APPLICATIONS

The present application claims the priority to Chinese Patent Application No. 202410313332.9, filed on Mar. 18, 2024. The entire disclosures of the above application are incorporated herein by reference.

### FIELD OF INVENTION

The present invention relates to a field of displays, especially to a display device.

### BACKGROUND OF INVENTION

Storage solutions for products with flexible display screens mainly consist of two methods: folding and rolling. The purpose is to reduce or restore the volume or area of the product by unfolding or storing the display screen through folding or rolling, thereby achieving portability. Currently, there are few methods for unfolding and storing display screens in display devices, leaving room for improvement.

Therefore, there is an urgent need for a display device to address the above technical issue.

### SUMMARY OF INVENTION

The present invention provides a display device that can increase methods for unrolling and storing display screen, thereby achieving dual-sided display of the display device and improving a product quality of the display device.

The present invention provides a display device, comprising:
a casing, wherein an accommodation chamber is defined in the casing;
a first winding assembly at least partially disposed in the accommodation chamber;
a lifting assembly at least partially disposed in the accommodation chamber, wherein the lifting assembly is located on a side of the first winding assembly along a first direction;
a transmission assembly connected to the first winding assembly and the lifting assembly, wherein the transmission assembly comprises a fastening member at least partially disposed in the accommodation chamber, the fastening member and the lifting assembly are located on a same side of the first winding assembly along the first direction; and
a display screen, wherein a first end of the display screen is connected to the first winding assembly, and a second end of the display screen is connected to the fastening member;
wherein the lifting assembly is located between the first end of the display screen and the second end of the display screen, the display device comprises a first state and a second state, and under the first state, the display screen is accommodated in the accommodation chamber;
wherein under the second state, the display screen is at least partially located outside the accommodation chamber, the transmission assembly controls the lifting assembly to move relative to the casing along the first direction and controls the first winding assembly rotate relative to the casing along a second direction to drive the display screen along the first direction to move relative to the casing, and the second direction intersects the first direction.

In some embodiments, the transmission assembly further comprises a first power member, the first power member controls the first winding assembly to rotate relative to the casing along the second direction, and the first power member comprises a first driver element disposed securely on the casing and a first connection element connected between the first driver element and the first winding assembly.

In some embodiments, the first winding assembly comprises a first winding shaft member and a first rotation member, the first winding shaft member is rotatably connected to the casing, the first rotation member is disposed securely on at least one side of the first winding shaft member along a third direction, the third direction intersects the first direction and is parallel to an extension direction of the first winding shaft member; and
the first connection element is connected between the first driver element and the first rotation member.

In some embodiments, the display screen comprises a connection portion, the connection portion is located on a first end of the display screen, the connection portion is disposed securely on the first winding shaft member.

In some embodiments, the display device further comprises a second winding assembly at least partially disposed in the accommodation chamber, the second winding assembly comprises a second winding shaft member and a protection member, the second winding shaft member is rotatably connected to the casing, an extension direction of the second winding shaft member is parallel to the extension direction of the first winding shaft member, a first end of the protection member is disposed securely on the second winding shaft member, a second end of the protection member is disposed securely on the first winding shaft member, and under the first state, the protection member is located between adjacent two loops of the display screen.

In some embodiments, the lifting assembly comprises a lifting member, a side of the lifting member near the first winding assembly along the first direction is disposed securely on the casing, and under the second state, a side of the lifting member away from the first winding assembly along the first direction along the first direction moves relative to the casing.

In some embodiments, the lifting assembly further comprises a third winding shaft member, an extension direction of the third winding shaft member is parallel to an extension direction of a first winding shaft member of the first winding assembly, a portion of the third winding shaft member contacts a non-display surface of the display screen, and the non-display surface of the display screen is disposed opposite to a display surface of the display screen.

In some embodiments, a surface of the third winding shaft member comprises a plurality of protrusions and/or recesses arranged along the extension direction of the third winding shaft member.

In some embodiments, the lifting member comprises an expansion element and an expansion orientation element, and under the second state, the expansion orientation element controls the expansion element to expand or contract along the first direction.

In some embodiments, the transmission assembly further comprises second power member, the second power member is disposed securely on the casing, and under the second state, the second power member controls a side of the lifting member away from the first winding assembly along the first direction to move relative to the casing along the first direction.

In some embodiments, the fastening member comprises a fastening element, a rotation shaft element, and an elastic element, the second end of the display screen is disposed securely on the fastening element, the fastening element is disposed securely on the rotation shaft element, the rotation shaft element is rotatably connected to the casing, an extension direction of the rotation shaft element is parallel to an extension direction of the first winding shaft member of the first winding assembly, a first end of the elastic element is disposed securely on at least one side of the rotation shaft element along a third direction, and a second end of the elastic element is disposed securely on the casing.

In some embodiments, the display screen further comprises a display part and a first wiring board located on a second end of the display part, and the first wiring board is disposed securely on the fastening element.

In some embodiments, the display device further comprises a third state, under the third state, the first winding assembly does not rotate relative to the casing, and the transmission assembly controls the lifting assembly to keep a displacement relative to the casing along the first direction under the second state.

The present invention also provides a display device, comprising:
a casing, wherein an accommodation chamber is defined in the casing;
a first winding assembly at least partially disposed in the accommodation chamber;
a lifting assembly at least partially disposed in the accommodation chamber, wherein the lifting assembly is located on a side of the first winding assembly along a first direction;
a transmission assembly connected to the first winding assembly and the lifting assembly, wherein the transmission assembly comprises a fastening member at least partially disposed in the accommodation chamber, the fastening member and the lifting assembly are located on a same side of the first winding assembly along the first direction; and
a display screen, wherein a first end of the display screen is connected to the first winding assembly, and a second end of the display screen is connected to the fastening member;
wherein the lifting assembly is located between the first end of the display screen and the second end of the display screen, the display device comprises a first state and a second state, and under the first state, the display screen is accommodated in the accommodation chamber;
wherein under the second state, the display screen is at least partially located outside the accommodation chamber, the transmission assembly controls the lifting assembly to move relative to the casing along the first direction and controls the first winding assembly rotate relative to the casing along a second direction to drive the display screen along the first direction to move relative to the casing, and the second direction intersects the first direction;
wherein the transmission assembly further comprises a first power member, the first power member controls the first winding assembly to rotate relative to the casing along the second direction, and the first power member comprises a first driver element disposed securely on the casing and a first connection element connected between the first driver element and the first winding assembly;
wherein the lifting assembly comprises a lifting member, a side of the lifting member near the first winding assembly along the first direction is disposed securely on the casing, and under the second state, a side of the lifting member away from the first winding assembly along the first direction along the first direction moves relative to the casing.

The present invention disposes the lifting assembly between the first end and the second end of the display screen, and drives the transmission assembly to synchronously controls movements of the lifting assembly and the first winding assembly to further drive the display screen to move along a first direction, thereby achieving unrolling and storing the display screen, reducing exposure of the lifting assembly, and improving a product quality of the display device.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may also acquire other figures according to the appended figures without any creative effort.

FIG. 1 is a schematic structural view of a first structure of a conventional display device;

FIG. 2 is a schematic structural view of a second structure of the conventional display device;

FIG. 3 is a schematic structural view of a third structure of the conventional display device;

FIG. 4 is a schematic structural view of a first structure of a display device provided by an embodiment of the present invention;

FIG. 5 is a schematic structural view of a second structure of the display device provided by the embodiment of the present invention;

FIG. 6 is a schematic structural view of a third structure of the display device provided by the embodiment of the present invention;

FIG. 7 is a schematic structural view of a fourth structure of the display device provided by the embodiment of the present invention;

FIG. 8 is a schematic structural view of a fifth structure of the display device provided by the embodiment of the present invention;

FIG. 9 is a schematic structural view of a sixth structure of the display device provided by the embodiment of the present invention;

FIG. 10 is a schematic structural view of a seventh structure of the display device provided by the embodiment of the present invention;

FIG. 11 is a first schematic structural view of a lifting member of the display device provided by the embodiment of the present invention;

FIG. 12 is a second schematic structural view of the lifting member of the display device provided by the embodiment of the present invention;

FIG. 13 is a schematic structural view of a sealing member of the display device provided by the embodiment of the present invention 1;

FIG. 14 is a first schematic structural view of a of a fastening member of the embodiment of the present invention;

FIG. 15 is a second schematic structural view of a of the fastening member of the embodiment of the present invention;

FIG. 16 is a third schematic structural view of a of the fastening member of the embodiment of the present invention;

FIG. 17 is a fourth schematic structural view of a of the fastening member of the embodiment of the present invention; and

FIG. 18 is a schematic structural view of a fastening hole of the display device provided by the embodiment of the present invention.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device.

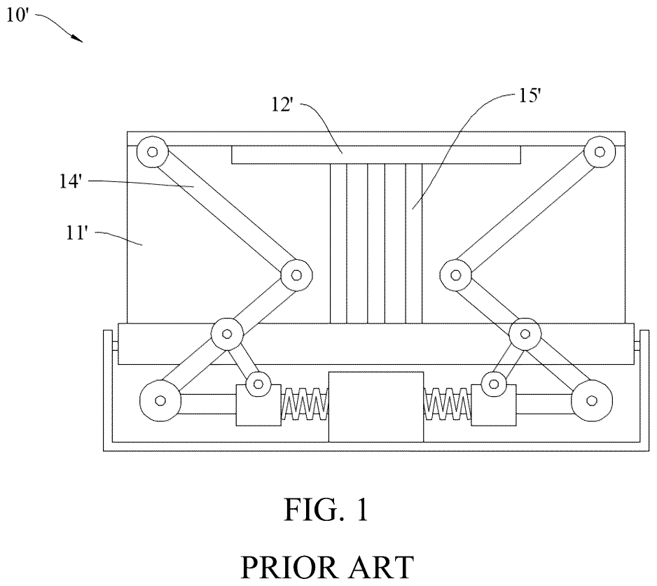

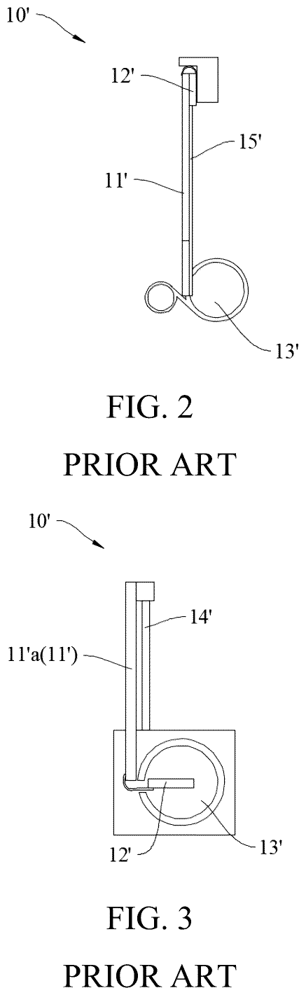

At present, a display device mainly comprises the following two methods for achieving storing and unrolling a display screen: First, with reference to FIGS. 1 and 2, a wiring board 12′ of a display screen 11′ is disposed away from a side of the winding shaft 13′, which causes a top portion of the display screen 11′ to be thick, and an exposed link bar 14′ is used to influence an appearance. Also, a connection line 15′ between the wiring board 12′ of the display screen 11′ and a wiring board of the central motherboard is bonded to a non-display surface of display screen 11′ so the connection line 15′ participates in rolling, which not only increases a thickness of the screen but also increases a risk of the connection line 15′ falling off or damaged, thereby resulting in the difficulty to improve the product quality of a display device 10′. Second, with reference to FIG. 3, the unrolling of the display screen 11′ also employs the exposed link bar 14′, thereby influencing the appearance. The wiring board 12′ of the display screen 11′ is disposed securely in the winding shaft 13′. When the display screen 11′ is rolled, the wiring board 12′ of the display screen 11′ also rotates with the winding shaft 13′, which easily causes damages of the wiring board 12′ of the display screen 11′. To accommodate the wiring board 12′ of the display screen 11′, and a diameter of the winding shaft 13′ cannot be decreased. A display part 11′a of the display screen 11′ cannot be exposed completely, and a rotational space of the connection line 15′ is limited such that a risk of damages of the connection lines 15′ is also increased, thereby resulting in the difficulty of improving the product quality of the display device 10′.

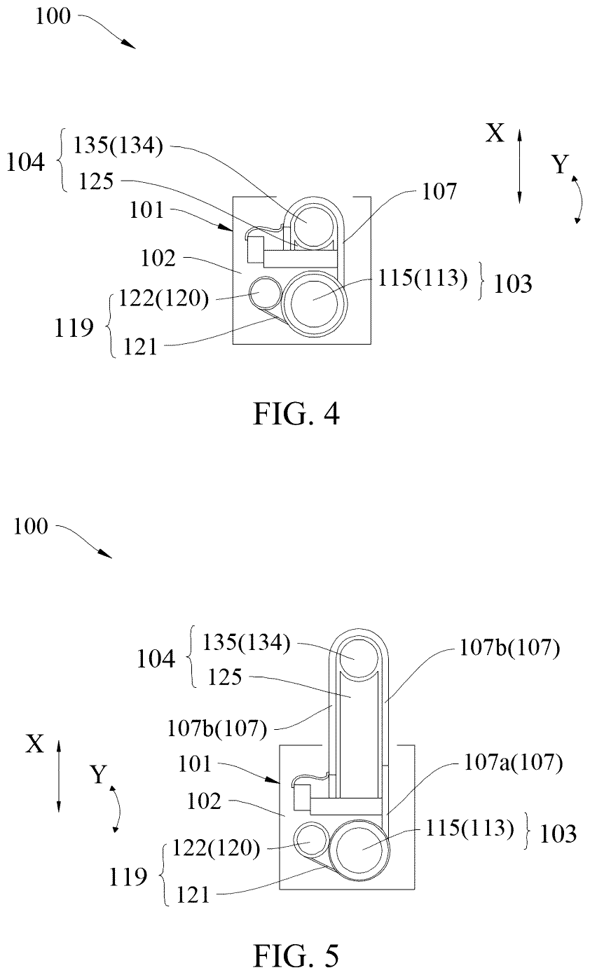

With reference to FIGS. 4 to 10, the embodiment of the present invention provides a display device 100, comprises:
a casing 101, the casing 101 disposed in an accommodation chamber 102;
a first winding assembly 103 at least partially disposed in the accommodation chamber 102;
a lifting assembly 104 at least partially disposed in the accommodation chamber 102, wherein the lifting assembly 104 is located on a side of the first winding assembly 103 along a first direction X;
a transmission assembly 105 connected to the first winding assembly 103 and the lifting assembly 104, wherein the transmission assembly 105 comprises a fastening member 106 at least partially disposed in the accommodation chamber 102, and the fastening member 106 and the lifting assembly 104 are located on the same side of the first winding assembly 103 along the first direction X;
a display screen 107, wherein a first end of the display screen 107 is connected to the first winding assembly 103, and a second end of the display screen 107 is connected to the fastening member 106;
wherein the lifting assembly 104 is located between the first end of the display screen 107 and the second end of the display screen 107, the display device 100 comprises a first state and a second state, and under the first state, the display screen 107 is accommodated in the accommodation chamber 102;
wherein under the second state, the display screen 107 is at least partially located outside the accommodation chamber 102, the transmission assembly 105 controls the lifting assembly 104 to move relative to the casing 101 along the first direction X and controls the first winding assembly 103 to rotate relative to the casing 101 along a second direction Y to drive the display screen 107 to move relative to the casing 101 along the first direction X, and the second direction Y intersects the first direction X.

The embodiment of the present invention disposes the lifting assembly 104 between the first end and the second end of the display screen 107 and utilizes the transmission assembly 105 to synchronously control move of the lifting assembly 104 and rotation of the first winding assembly 103 to further drive the display screen 107 to move relative to the casing 101 along the first direction X, thereby reducing exposure of the lifting assembly 104 and improving the product quality of the display device 100 while achieving storing and unrolling the display screen 107.

Technical solutions of the present invention are described in combination with specific embodiments as follows.

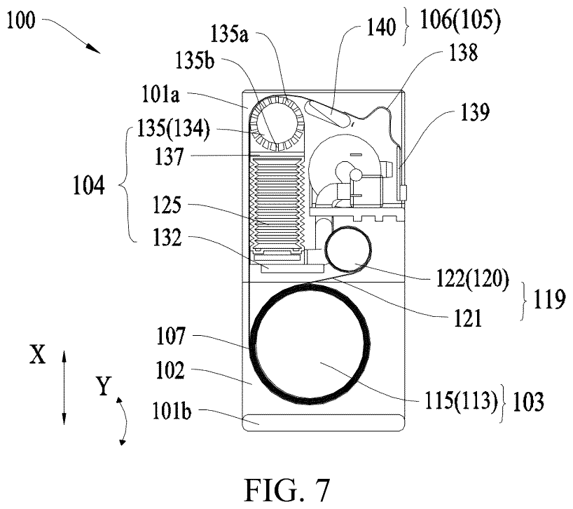

With reference to FIGS. 4 to 7, in the present embodiment, the accommodation chamber 102 is a space formed in the casing 101. Under the second state, the transmission assembly 105 (as shown in FIG. 7) controls the lifting assembly 104 such that the lifting assembly 104 moves relative to the casing 101 along the first direction X. Also, at least a part of members of the first winding assembly 103 located in the accommodation chamber 102 rotates relative to the casing 101 along the second direction Y in the accommodation chamber 102.

With reference to FIGS. 4 and 7, in the present embodiment, under the first state, the display screen 107 is accommodated in the accommodation chamber 102, the display screen 107 is in a non-displaying state, and the first winding assembly 103, the lifting assembly 104, and the transmission assembly 105 are in a non-working state. Namely, the first winding assembly 103 does not rotate relative to the casing 101, the lifting assembly 104 does not move relative to the casing 101 along the first direction X, and the transmission assembly 105 (as shown in FIG. 7) also does not control the first winding assembly 103 and the lifting assembly 104 to act relative to the casing 101. Under the second state, the display screen 107 is at least partially located outside the accommodation chamber 102, and the first winding assembly 103, the lifting assembly 104, and the transmission assembly 105 (as shown in FIG. 7) are in a working state. Namely, under control of the transmission assembly 105, the first winding assembly 103 rotates relative to the casing 101, and the lifting assembly 104 moves relative to the casing 101 along the first direction X. Under the second state, the display screen 107 is in a displaying state or the non-displaying state.

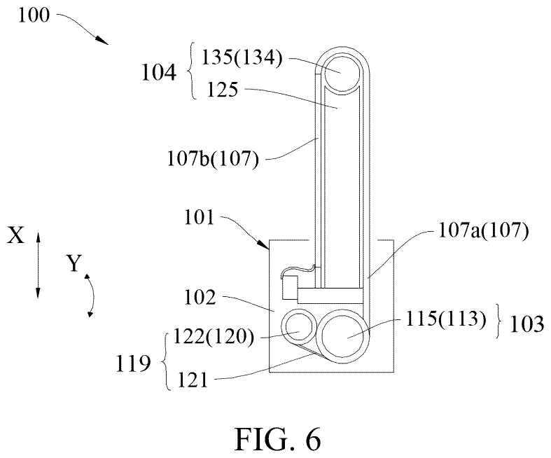

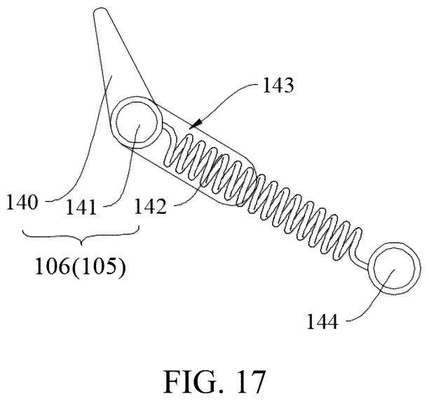

With reference to FIGS. 5 and 6, in some embodiments, the display device 100 further comprises a third state. Under the third state, the display screen 107 is at least partially located outside the accommodation chamber 102, the first winding assembly 103 is in the non-working state, and the lifting assembly 104 and the transmission assembly 105 (as shown in FIGS. 16 and 17) are in the working state. In the meantime, the first winding assembly 103 stops rotating relative to the casing 101 (namely, the first winding assembly 103 relative to the casing 101 does not rotate), the transmission assembly 105 controls the lifting assembly 104 to keep a displacement relative to the casing 101 along the first direction X under the second state. The display screen 107 is in the displaying state. The display screen 107 comprises a display part 107b, and the display part 107b is partially or completely located outside the accommodation chamber 102. The display screen 107 is in a completely unrolling state or a partially unrolling state. Because the lifting assembly 104 is located between the first end of the display screen 107 and the second end of the display screen 107, the display screen 107 under the third state can implement dual-sided display or a single-sided display.

In some embodiments, the display screen 107, by the display device 100 switching sequentially to the first state, the second state, and the third state, implements completely unrolling or partially unrolling. The display screen 107, by the display device 100 switching sequentially to the third state, the second state, the first state, implements complete reception in the accommodation chamber 102.

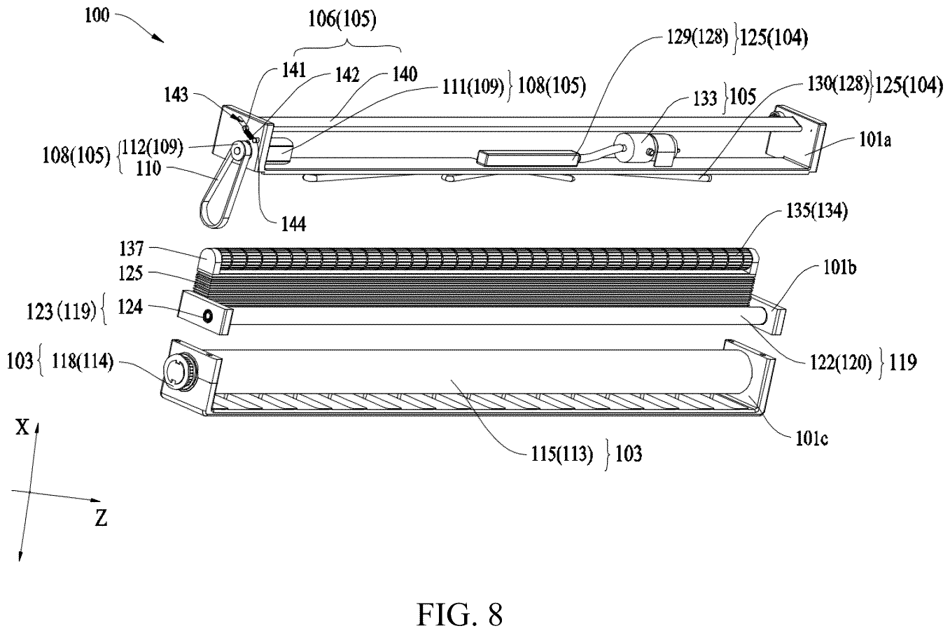

With reference to FIGS. 8 to 9, 14, and 16, in the present embodiment, the transmission assembly 105 further comprises a first power member 108, and the first power member 108 controls the first winding assembly 103 to rotate relative to the casing 101 along the second direction Y. The first power member 108 comprises a first driver element 109 disposed securely on the casing 101 and a first connection element 110 connected between the first driver element 109 and the first winding assembly 103.

With reference to FIGS. 8 to 9, 14, and 16, in some embodiments, the first driver element 109 comprises a transmission motor 111 and a first transmission gear 112. The transmission motor 111 is connected to the first transmission gear 112. The transmission motor 111 is located in the accommodation chamber 102. Under the second state, the transmission motor 111 supplies the first transmission gear 112 with power to control the first transmission gear 112 to rotate relative to the casing 101 along a fourth direction. The first connection element 110 transmits rotation to the first winding assembly 103 to control the first winding assembly 103 to rotate relative to the casing 101 along the second direction Y. The transmission motor 111 is disposed securely on the casing 101. The first transmission gear 112 can be located in the accommodation chamber 102, and can be located outside the accommodation chamber 102. The first transmission gear 112 located outside the accommodation chamber 102 facilitates reduction of occupation of the space inside the accommodation chamber 102, thereby reducing the volume of the accommodation chamber 102 and improving the portability of the display device 100.

With reference to FIGS. 7 to 9, in some embodiments, the first winding assembly 103 comprises a first winding shaft member 113 and a first rotation member 114. The first winding shaft member 113 is rotatably connected to the casing 101. The first rotation member 114 is disposed securely on at least one side of the first winding shaft member 113 along a third direction Z. The third direction Z intersects the first direction X, and the third direction Z is parallel to an extension direction of the first winding shaft member 113.

With reference to FIGS. 7 to 9, in some embodiments, the first winding shaft member 113 comprises a first winding shaft 115, the third direction Z is parallel to an extension direction of the first winding shaft 115, and two ends of the first winding shaft 115 are rotatably connected to the casing 101 along the third direction Z.

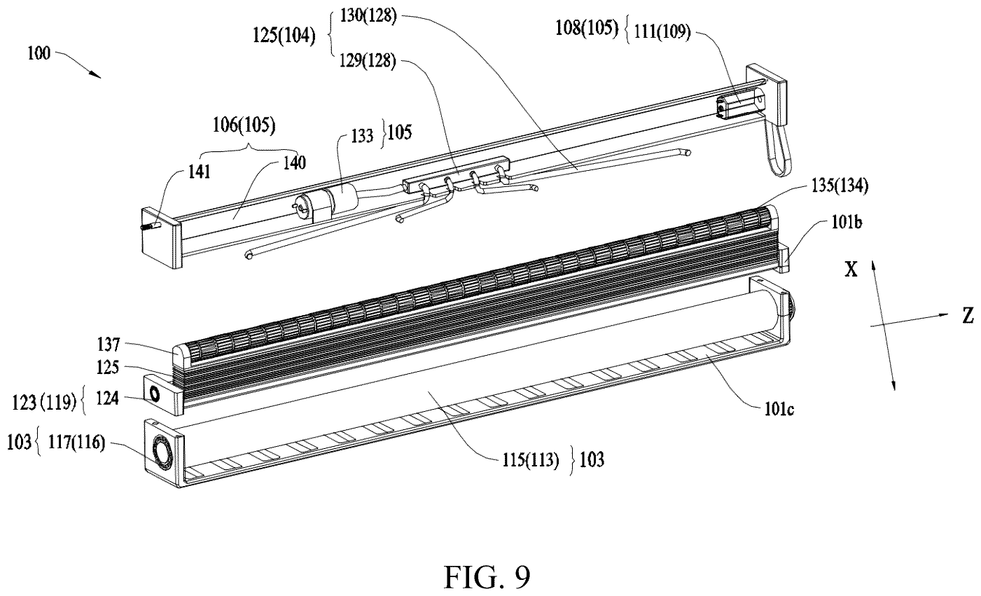

With reference to FIG. 9, in some embodiments, the first winding assembly 103 further comprises a first bearing member 116, and the first bearing member 116 is disposed securely on the casing 101. The first bearing member 116 comprises at least two first bearings 117, and the at least two first bearings 117 are located respectively at two ends of the first winding shaft 115 along the third direction Z. The first winding shaft 115 is rotatably connected to the casing 101 by the first bearings 117.

With reference to FIG. 8, in some embodiments, the first rotation member 114 comprises a second transmission gear 118, and the second transmission gear 118 is disposed securely on at least one side of the first winding shaft 115 along the third direction Z. Preferably, the first rotation member 114 comprises two second transmission gears 118, and the two second transmission gears 118 along the third direction Z are securely disposed respectively on two sides of the first winding shaft 115.

In some embodiments, the two second transmission gears 118 are connected securely to the first winding shaft 115 in the first bearings 117. Under the second state, a driving force provided by the first driver element 109 is transmitted through the first connection element 110 to the second transmission gear 118. The second transmission gear 118 rotates relative to the casing 101 along the fourth direction or rotates along a direction opposite to the fourth direction to drive the first winding shaft 115 to rotate relative to the casing 101 along the second direction Y. The second direction Y is the same as or opposite to the fourth direction. The second direction Y can be a clockwise direction, and can be a counterclockwise direction. The second transmission gear 118 can be located outside the accommodation chamber 102, and can be located in the accommodation chamber 102. The second transmission gear 118 is located outside the accommodation chamber 102 facilitates reduction occupation to the space in the accommodation chamber 102, reduction the volume f the accommodation chamber 102, and improvement of the portability of the display device 100.

With reference to FIGS. 14 and 16, in some embodiments, the first connection element 110 is connected between the first driver element 109 and the first rotation member 114. In particular, the first connection element 110 can be a transmission strip connected between the first transmission gear 112 and the second transmission gear 118, for example, it can be a transmission belt.

With reference to FIGS. 5 and 6, in some embodiments, the display screen 107 comprises a connection portion 107a, the connection portion 107a is located at the first end of the display screen 107, and the connection portion 107a is disposed securely on the first winding shaft member 113. The connection portion 107a is connected between the display part 107b and the first winding shaft member 113. The connection portion 107a can have no display function such that the display screen 107 in the third state can completely expose the display part 107b of the display screen 107 out of the accommodation chamber 102, thereby increasing the display area of the display device 100. The connection portion 107a can be bonded securely to the first winding shaft 115 of the first winding shaft member 113.

With reference to FIGS. 7 to 8, in some embodiments, the display device 100 further comprises a second winding assembly 119 at least partially disposed in the accommodation chamber 102. The second winding assembly 119 comprises a second winding shaft member 120 and a protection member 121. The second winding shaft member 120 is rotatably connected to the casing 101. An extension direction of the second winding shaft member 120 is parallel to the extension direction of the first winding shaft member 113. A first end of the protection member 121 is disposed securely on the second winding shaft member 120, and a second end the protection member 121 is disposed securely on the first winding shaft member 113. Under the first state, the protection member 121 is located between adjacent two loops of the display screen 107. The configuration of the protection member 121 between adjacent two loops of the display screen 107 facilitates reducing or preventing scratches of the display screen 107 resulting from friction between a display surface of the display screen 107 and a non-display surface of an adjacent loop of the display screen 107 during the display screen 107 being rolled and stored in the first winding shaft 115, which advantages improving of the product quality of the display device 100.

In some embodiments, the protection member 121 can be material having a cushioning property and able to contain a certain amount of foreign matters to reduce quality issues such as scratches due to the display screen 107 being rolled in the first winding shaft member 113. For example, material of the protection member 121 can be flannel.

With reference to FIGS. 4 to 8, in some embodiments, the second winding shaft member 120 comprises a second winding shaft 122, and two ends of the second winding shaft 122 are rotatably connected to the casing 101 along the third direction Z. An extension direction of the second winding shaft 122 is parallel to the extension direction of the first winding shaft 115. Under the second state, the first winding shaft 115 rotates relative to the casing 101 along the second direction Y to drive the protection member 121 to move relative to the casing 101 between the first winding shaft 115 and the second winding shaft 122. The move of the protection member 121 drives the second winding shaft 122 to rotate relative to the casing 101 along a fifth direction. The fifth direction is opposite to the second direction Y. In particular, under the second state, along the first direction X, when the first end of the display screen 107 moves along a direction away from the first winding assembly 103, the protection member 121 moves along a direction from the first winding shaft 115 to the second winding shaft 122. Along the first direction X, when the first end of the display screen 107 moves along a direction near the first winding assembly 103, the protection member 121 moves along a direction from the second winding shaft 122 to the first winding shaft 115.

With reference to FIGS. 7 to 9, in some embodiments, the second winding assembly 119 and the lifting assembly 104 are located on the same side of the first winding assembly 103 along the first direction X to improve a space utilization rate in the accommodation chamber 102, reduce a volume of the accommodation chamber 102, and enhance the portability of the display device 100.

With reference to FIG. 9, in some embodiments, the second winding assembly 119 further comprises a second bearing member 123. The second bearing member 123 is disposed securely on the casing 101, and the second bearing member 123 comprises at least two second bearings 124. The at least two second bearings 124 are located respectively at two ends of the second winding shaft 122 along the third direction Z. The second winding shaft 122 is rotatably connected to the casing 101 by the second bearings 124. For example, the second bearings 124 are disposed securely on the casing 101, and two ends of the second winding shaft 122 along the third direction Z are at least partially located respectively in the second bearings 124.

With reference to FIGS. 4 to 9, in some embodiments, the lifting assembly 104 comprises a lifting member 125, and a side of the lifting member 125 near the first winding assembly 103 along the first direction X is disposed securely on the casing 101. Under the first state, the lifting member 125 is located in the accommodation chamber 102. Under the second state, a side of the lifting member 125 away from the first winding assembly 103 along the first direction X moves relative to the casing 101 along the first direction X.

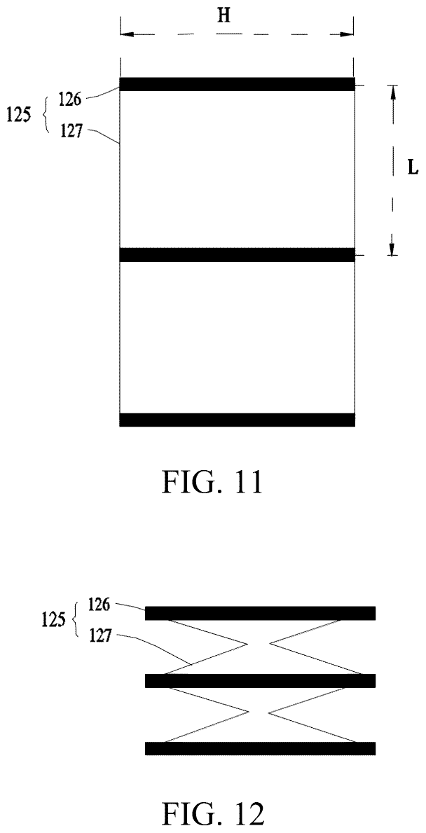

With reference to FIGS. 11 and 12, in some embodiments, the lifting member 125 comprises an expansion element 126 and an expansion orientation element 127. Under the second state, the expansion orientation element 127 controls an expansion or contract direction of the expansion element 126 to control the expansion element 126 to expand or contract along the first direction X to achieve the move of the lifting assembly 104 relative to the casing 101 along the first direction X.

In some embodiments, the expansion element 126 can be an airbag. The expansion orientation element 127 can comprise a rigid collar disposed around the airbag. The rigid collar is disposed securely on an outer wall or an inner wall of the airbag. The rigid collar can be plural, and the rigid collars are arranged along the first direction X to control the airbag to expand or contract along the first direction X (as shown in FIGS. 11 and 12).

In some embodiments, the rigid collar can be an annular wire.

With reference to FIG. 11, in some embodiments, when the display screen 107 is is in the completely unrolling state, a displacement of the lifting assembly 104 relative to the casing 101 along the first direction X reaches a maximum, and the interval between adjacent ones of the rigid collar also reaches a maximum.

With reference to FIG. 11, in some embodiments, when the display screen 107 is in the completely unrolling state, a maximum value of an interval of adjacent ones of the rigid collars can be represented by L, a width of the airbag along a direction perpendicular to the first direction X is represented by H. A thickness of a side of the airbag along a direction perpendicular to the first direction X is represented by a. Then, the maximum value of the interval between adjacent ones of the rigid collars can be calculated by the following formula:

L=H−2a

In some embodiments, when His 20 mm and a is 0.65 mm, L can be 18.7 mm. Namely, the maximum value of the interval between adjacent ones of the rigid collars can be 18.7 mm. When the display screen 107 is in the completely unrolling state, the interval between adjacent ones of the rigid collar can be less than or equal to 18.7 mm, for example, can be 17 mm, 16 mm, 15 mm, 14 mm, 13 mm, 12 mm, 11 mm, 10 mm, 9 mm, 8 mm, 7 mm, 6 mm, 5 mm, etc.

With reference to FIGS. 8 to 9, and 13, in some embodiments, the lifting member 125 further comprises a medium filling element 128, the medium filling element 128 is disposed securely on the casing 101. Under the second state, a fill medium filled in the expansion element 126 is filled in the expansion element 126 by the medium filling element 128. When the expansion element 126 is an airbag, the medium filling element 128 conveys gas (for example: air) into the airbag. The medium filling element 128 comprises a medium fill casing 129 and at least one duct 130 connected to the medium fill casing 129. A medium storage chamber is defined in the medium fill casing 129. The duct 130 is connected between the medium storage chamber and the expansion element 126 such that the fill medium flows between the medium storage chamber and the expansion element 126.

In some embodiments, a valve is disposed on a connection location where the duct 130 or the medium storage chamber is connected to the duct 130. When a pressure in the medium storage chamber reaches a threshold, the valve opens, and the fill medium is filled through the duct 130 into the expansion element 126.

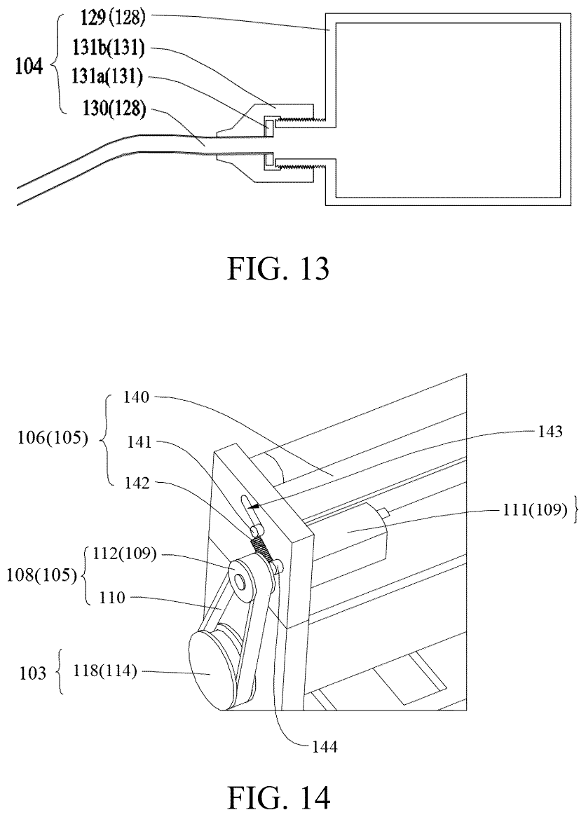

With reference to FIG. 13, in some embodiments, the lifting assembly 104 further comprises a sealing member 131, and the sealing member 131 is disposed securely on a connection location between the duct 130 and the medium fill casing 129 to prevent leakage of the fill medium causing insufficient displacement of the lifting assembly 104 relative to the casing 101 under the second state and further resulting in non-synchronization with the move of the display screen 107 relative to the casing 101 along the first direction X to lead to issues such as damages of the display screen 107.

With reference to FIG. 13, in some embodiments, the sealing member 131 comprises a sealing adhesive strip 131a surrounding a connection location between the duct 130 and the medium fill casing 129 and a nut 131b. The nut 131b matches a thread on the medium fill casing 129 to achieve sealing on the connection location between the duct 130 and the medium fill casing 129.

With reference to FIG. 7, in some embodiments, the lifting assembly 104 further comprises a first carrier member 132, the first carrier member 132 is disposed securely on the casing 101, and a side of the expansion element 126 near the first winding assembly 103 is disposed securely on the first carrier member 132.

With reference to FIGS. 8 to 9, in some embodiments, the transmission assembly 105 further comprises a second power member 133, and the second power member 133 is disposed securely on the casing 101. Under the second state, the second power member 133 controls a side of the lifting member 125 away from the first winding assembly 103 along the first direction X to move relative to the casing 101 along the first direction X. When the lifting member 125 comprises an expansion element 126, the second power member 133 provides the fill medium and provides a power filling the fill medium into the expansion element 126 or pumping the fill medium out of the expansion element 126. For example, the second power member 133 can be an electric air pump.

With reference to FIGS. 4 to 9, in some embodiments, the lifting assembly 104 further comprises a third winding shaft member 134. An extension direction of the third winding shaft member 134 is parallel to the extension direction of the first winding shaft member 113 of the first winding assembly 103. A portion of the third winding shaft member 134 contacts the non-display surface of the display screen 107. The non-display surface of the display screen 107 is disposed opposite to the display surface of the display screen 107. The first end of the display screen 107 and the second end of the display screen 107 are located respectively on two opposite sides of the third winding shaft member 134. When the display device 100 is in the first state, an area of the display screen 107 located between the third winding shaft member 134 and the second end of the display screen 107 is less than an area of the display screen 107 between the third winding shaft member 134 and the first end of the display screen 107. When the display device 100 is in the second state between the first state and the third state, the display screen 107 changes from a complete accommodation state to the completely unrolling state. A portion of the display screen 107 originally located between the first end of the display screen 107 and the third winding shaft member 134 moves to a location between the second end of the display screen 107 and the third winding shaft member 134. When the display screen 107 is in the completely unrolling state, the area of the display screen 107 between the second end of the display screen 107 and the third winding shaft member 134 reaches a maximum. The display part 107b of the display screen 107 between the first end of the display screen 107 and the third winding shaft member 134, and the display part 107b of the display screen 107 between the second end of the display screen 107 and the third winding shaft member 134 can be utilized for display. In the meantime, the display screen 107 can be used for dual-sided display. When the display screen 107 is in the completely unrolling state, the area of the display screen 107 between the second end of the display screen 107 and the third winding shaft member 134 reaches a maximum, and the display part 107b of the display screen 107 is located between the second end of the display screen 107 and the third winding shaft member 134. At this time, the display screen 107 is used for single-sided display, and the connection portion 107a of display screen 107 is partially located between the first end of the display screen 107 and the third winding shaft member 134. When the display device 100 is in the second state changing from the third state to the first state, the display screen 107 changes from the completely unrolling state to the complete accommodation state, and a portion of the display screen 107 originally located between the second end of the display screen 107 and the third winding shaft member 134 moves to a location between the first end of the display screen 107 and the third winding shaft member 134.

With reference to FIGS. 4 to 9, in some embodiments, the third winding shaft member 134 comprises a third winding shaft 135, an extension direction of the third winding shaft 135 is parallel to the extension direction of the first winding shaft member 113 of the first winding assembly 103. Under the second state, the display screen 107 moves between the first end of the display screen 107 and the third winding shaft 135, and moves between the second end of the display screen 107 and the third winding shaft 135. The third winding shaft 135 provides the display screen 107 with a supporting force, and the third winding shaft 135 rotates relative to the casing 101 with the move of the display screen 107, which facilitates the display screen 107 moving from a location between the first end of the display screen 107 and the third winding shaft 135 to a location between the second end of the display screen 107 and the third winding shaft 135, and facilitates the display screen 107 moving from the location between the second end of the display screen 107 and the third winding shaft 135 to the location between the first end of the display screen 107 and the third winding shaft 135 while reducing wear of the display screen 107.

With reference to FIG. 7, in some embodiments, a surface of the third winding shaft member 134 comprises a plurality of protrusions 135a and/or recesses 135b arranged along the extension direction of the third winding shaft member 134. The configuration of the protrusions 135a and/or the recesses 135b facilitates increasing frictions between a backlight surface of the display screen 107 and the third winding shaft member 134 such that the display screen 107 can drive the third winding shaft 135 to rotate to facilitate the display screen 107 moving from the location between the first end of the display screen 107 and the third winding shaft 135 to the location between the second end of the display screen 107 and the third winding shaft 135, and facilitates the display screen 107 moving from the location between the second end of the display screen 107 and the third winding shaft 135 to the location between the first end of the display screen 107 and the third winding shaft 135.

In some embodiments, the protrusions 135a of the surface of the third winding shaft member 134 can be divided into a plurality of protrusion sets. The protrusion sets are arranged along the extension direction of the third winding shaft 135. Each of the protrusion sets comprises at least one the protrusions 135a. When each of the protrusion sets comprises the protrusions 135a, the protrusions 135a in each of the protrusion sets are arranged continuously along a direction around an axis of the third winding shaft 135.

In some embodiments, the recesses 135b of a surface of the third winding shaft 135 can comprise first recesses and second recesses. The first recesses are divided into first recess sets, and the second recesses are divided into second recess sets. The first recess sets and the second recess sets are arranged along the extension direction of the third winding shaft 135. The second recess set is disposed between adjacent two of the first recess sets. Each of the first recess sets comprises at least one the first recesses. Each of the second recess sets comprises one second recess. When each of the first recess sets comprises the first recesses, the first recesses in each of the first recess sets are arranged continuously along a direction around the axis of the third winding shaft 135.

In some embodiments, when the surface of the third winding shaft 135 comprises the protrusions 135a and the recesses 135b, the protrusions 135a in the protrusion sets and the first recesses in the first recess sets are arranged alternately along the direction around the axis of the third winding shaft 135.

With reference to FIGS. 7 to 9, in some embodiments, the lifting assembly 104 further comprises a second carrier member 137, and the second carrier member 137 is disposed securely on a side of the lifting member 125 away from the first winding assembly 103. The third winding shaft member 134 is rotatably connected to the second carrier member 137. The configuration of the second carrier member 137 achieves the third winding shaft member 134 moving with the lifting member 125 relative to the casing 101 along the first direction X under the second state.

In some embodiments, the lifting assembly 104 further comprises a third bearing member, and the third bearing member is disposed securely on the second carrier member 137. The third bearing member comprises at least two third bearings, and the at least two third bearings are located respectively at two ends of the third winding shaft 135 along the third direction Z. The third winding shaft 135 is rotatably connected to the second carrier member 137 by the third bearings. For example, the third bearings are disposed securely on the second carrier member 137, and two ends of the third winding shaft 135 are at least partially located respectively in the third bearings along an extension direction of the third winding shaft 135.

With reference to FIGS. 7 to 10 and 14 to 17, in some embodiments, the fastening member 106 comprises a fastening element 140, a rotation shaft element 141, and an elastic element 142. The second end of the display screen 107 is disposed securely on the fastening element 140. The fastening element 140 is disposed securely on the rotation shaft element 141. The rotation shaft element 141 is rotatably connected to the casing 101. An extension direction of the rotation shaft element 141 is parallel to the extension direction of the first winding shaft member 113 of the first winding assembly 103. A first end of the elastic element 142 is disposed securely on at least one side of the rotation shaft element 141 along the third direction Z. A second end of the elastic element 142 is disposed securely on the casing 101. The casing 101 comprises two sliding slots 143. The sliding slots 143 are located respectively at two ends of the rotation shaft element 141 along the extension direction of the rotation shaft element 141. The two ends of the rotation shaft element 141 along the extension direction of the rotation shaft element 141 are located respectively in the sliding slots 143. The elastic element 142 is located at least one end of the rotation shaft element 141 along the extension direction of the rotation shaft element 141. Preferably, the elastic element 142 is located at the two ends of the rotation shaft element 141 along the extension direction of the rotation shaft element 141. The elastic element 142 can be located in the accommodation chamber 102, and can be located outside the accommodation chamber 102. The casing 101 comprises a fastening post 144 located on a side of the sliding slot 143 near the first winding assembly 103, and the second end of the elastic element 142 is disposed securely on the fastening post 144.

With reference to FIGS. 16 and 17, under the second state changing from the first state to the third state, the display screen 107 moves relative to the casing 101 along the first direction X, the fastening element 140 undergoes a pull force from the second end of the display screen 107 fastened on the fastening element 140 and rotates and moves relative to the casing 101 to drive the rotation shaft element 141 to rotate relative to the casing 101 and move relative to the casing 101. A moving direction of the rotation shaft element 141 is parallel to a moving direction of the sliding slots 143. The rotation shaft element 141 moves toward a side away from the first winding assembly 103. Under the second state changing from the first state to the third state, the move and rotation of the fastening element 140 relative to the casing 101 facilitate the display screen 107 driving the display part 107b of the display screen 107 to be completely out of the accommodation chamber 102 under the completely unrolling state, thereby improving the display effect of the display screen 107 and enhancing the product quality of the display device 100.

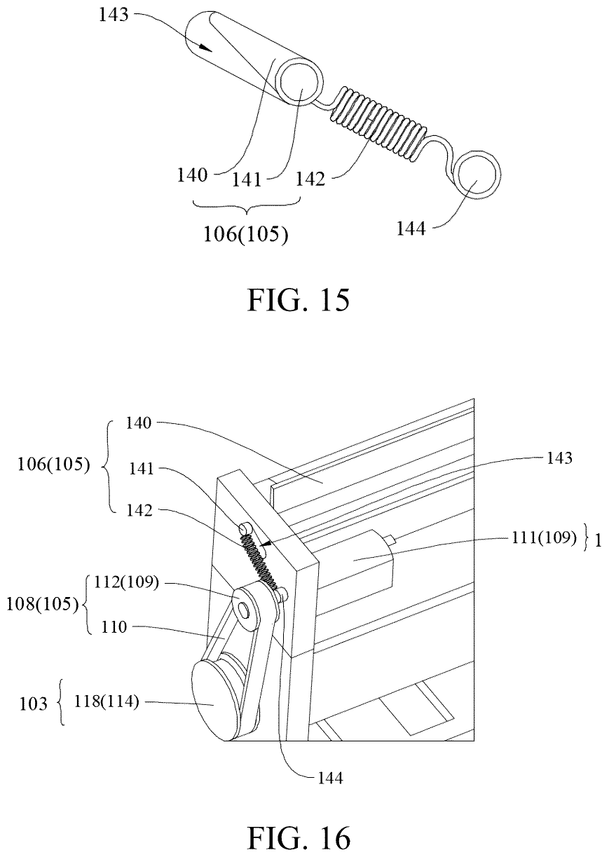

With reference to FIGS. 14 and 15, under the second state changing from the third state to the first state, the rotation shaft element 141, undergoes a pull force from the elastic element 142 to move and rotate relative to the casing 101 opposite to the move and rotation under the second state changing from the first state to the third state. The fastening element 140 accordingly moves and rotates relative to the casing 101 opposite to the move and rotation under the second state changing from the first state to the third state, which facilitates the display screen 107 completely accommodated in the accommodation chamber 102 under the first state.

In some embodiments, the fastening element 140 can be a slider. The elastic element 142 can be a spring.

In some embodiments, the fastening element 140 and the rotation shaft element 141 can be disposed integrally.

With reference to FIG. 7, in some embodiments, the display screen 107 further comprises a first wiring board 138 located at a second end of the display part 107b, and the first wiring board 138 is disposed securely on the fastening element 140. Fastening the first wiring board 138 on the fastening element 140 prevents the first wiring board 138 participating in rolling and moving of the display screen 107, thereby facilitating protecting the first wiring board 138, reducing damages of the connection lines among the first wiring board 138, the display screen 107, and the central motherboard, and improving the product quality of the display device 100.

In some embodiments, the first wiring board 138 can be bonded securely to the fastening element 140.

In some embodiments, the first wiring board 138 can be a chip on film (COF).

With reference to FIG. 7, in some embodiments, the display screen 107 further comprises a second wiring board 139. A first end of the first wiring board 138 is disposed securely on the fastening element 140, a second end of the first wiring board 138 is connected to the second wiring board 139, and the second wiring board 139 is located in the accommodation chamber 102.

In some embodiments, the second wiring board 139 can be a printed circuit board (PCB). The configuration of the second wiring board 139 inside the accommodation chamber 102 prevents the second wiring board 139 from participating in wind and move of the display screen 107, thereby facilitating protecting the second wiring board 139, reducing damages of connection lines among the second wiring board 139, the display screen 107, and the central motherboard, and improving the product quality of the display device 100.

In some embodiments, the display device 100 further comprises a third carrier member, the third carrier member is disposed securely on the casing 101, and the second wiring board 139 is disposed securely on the third carrier member.

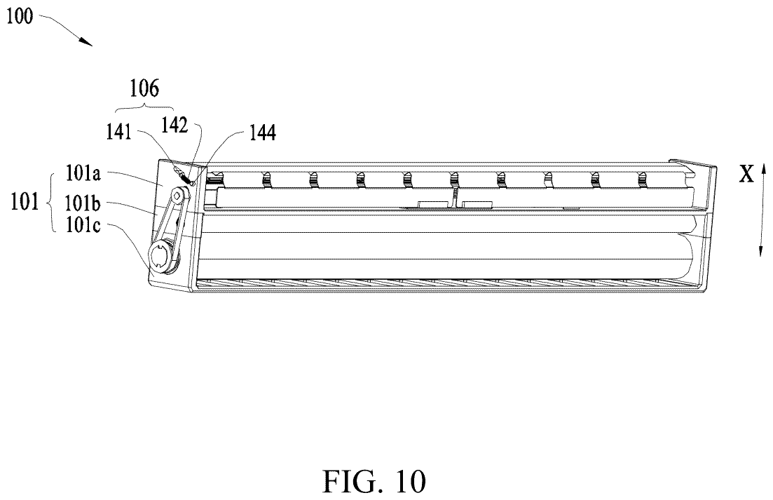

With reference to FIG. 10, in some embodiments, the casing 101 comprises a first casing assembly 101a, a second casing assembly 101b, and a third casing assembly 101c arranged along the first direction X. The first casing assembly 101a is located on a side of the second casing assembly 101b away from the first winding assembly 103. The third casing assembly 101c is located on a side of the second casing assembly 101b near the first winding assembly 103. The first assembly is connected securely to the second casing assembly 101b. The second casing assembly 101b is connected to the third casing assembly 101c to constitute the casing 101. The casing 101 is assembled by the first casing assembly 101a, the second casing assembly 101b, and the third casing assembly 101c, thereby facilitating simplification of fabrication processes of the casing 101, advantaging product maintenance of the display device 100, and prolonging the lifespan of the display device 100.

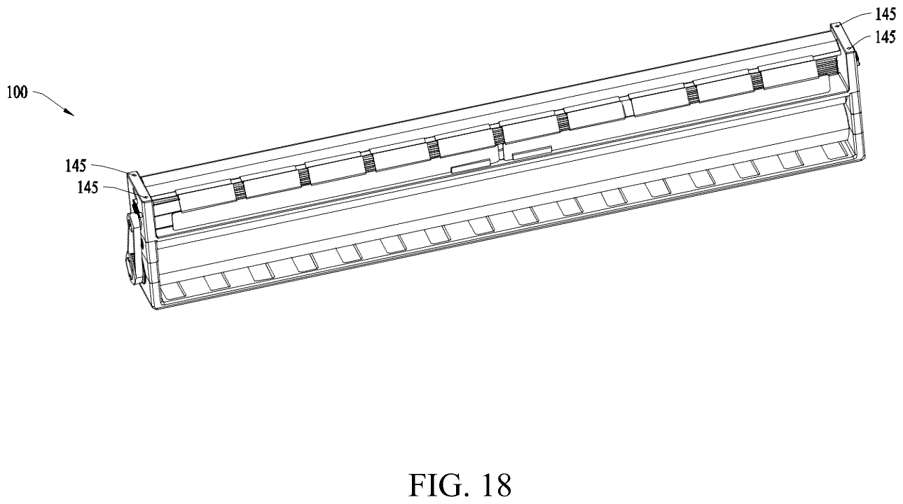

With reference to FIG. 18, in some embodiments, the first casing assembly 101a, the second casing assembly 101b, and the third casing assembly 101c are connected securely to one another by screws. The second casing assembly 101b is connected securely to the third casing assembly 101c by a screw. The display device comprises a fastening hole 145, the fastening hole 145 is defined through the first casing assembly 101a, the second casing assembly 101b, and the third casing assembly 101c along the first direction X such that the screw can be fastened through the fastening hole 145.

In some embodiments, a portion of the transmission assembly 105 is disposed securely on the first casing assembly 101a, for example, the fastening member 106, the first driver element 109, the second power member 133 is disposed securely on the first casing assembly 101a. A portion of the lifting assembly 104 is disposed securely on the first casing assembly 101a, for example, the medium filling element 128.

In some embodiments, a portion of the lifting assembly 104 is disposed securely on the second casing assembly 101b, for example, the first carrier member 132. A portion of the second winding assembly 119 is disposed securely on the second casing assembly 101b, for example, the second bearing member 123.

In some embodiments, a portion of the first winding assembly 103 is disposed securely on the third casing assembly 101c. For example, the first bearing member 116.

In some embodiments, along the first direction X, the first casing assembly 101a comprises a first coverplate, the first coverplate is located on a side away from the first winding assembly 103. The first coverplate comprises an aperture. Under the second state, the display screen 107 moves, through the aperture, relative to the casing 101 out of the accommodation chamber 102. The configuration of the first coverplate facilitates shielding each assembly in the accommodation chamber 102, reducing impurities such as dust from entering the accommodation chamber 102 and causing damages of the display device 100.

In some embodiments, the first casing assembly 101a further comprises a second coverplate, and the second coverplate is connected movably to the first coverplate. Alternatively, the second coverplate is rotatably connected to the first coverplate. Under the first state, the second coverplate covers the aperture, for example, the second coverplate is engaged with the aperture to further prevent impurities such as dust from entering the accommodation chamber 102 and causing damages of the display device 100. Under the second state or under the third state, the second coverplate moves or rotates relative to the casing 101 to expose the aperture to facilitate the display screen 107 moving out of the accommodation chamber 102.

The display device 100 disclosed by the embodiment of the present invention disposes the lifting assembly 104 between the first end and the second end of the display screen 107 and utilizes the transmission assembly 105 to synchronously control move of the lifting assembly 104 and rotation of the first winding assembly 103 to drive the display screen 107 to move relative to the casing 101 along the first direction X, thereby achieving storing and unrolling the display screen 107, reducing exposure of the lifting assembly 104, and improving the product quality of the display device 100.

The embodiment of the present invention discloses a display device. The display device comprises a casing, a first winding assembly, a lifting assembly, a transmission assembly, and a display screen disposed in an accommodation chamber. The transmission assembly comprises a fastening member at least partially disposed in the accommodation chamber. The lifting assembly is located between a first end of the display screen and a second end of the display screen. The display screen, under a first state, is received in the accommodation chamber. The display screen, under a second state, is located partially outside the accommodation chamber. The transmission assembly controls the lifting assembly to move along a first direction relative to the casing and the first winding assembly to rotate relative to the casing along a second direction to drive the display screen to move relative to the casing along the first direction. The present invention disposes the lifting assembly between the first end and the second end of the display screen, and drives the transmission assembly to synchronously controls movements of the lifting assembly and the first winding assembly to further drive the display screen to move along a first direction, thereby achieving unrolling and storing the display screen, reducing exposure of the lifting assembly, and improving a product quality of the display device.

The display device provided by the embodiment of the present invention is described in detail as above. In the specification, the specific examples are used to explain the principle and embodiment of the present application. The above description of the embodiments is only used to help understand the method of the present application and its spiritual idea. Meanwhile, for those skilled in the art, according to the present idea of invention, changes will be made in specific embodiment and application. In summary, the contents of this specification should not be construed as limiting the present application.

1. A display device, comprising:
a casing, wherein an accommodation chamber is defined in the casing;
a first winding assembly at least partially disposed in the accommodation chamber;
a lifting assembly at least partially disposed in the accommodation chamber, wherein the lifting assembly is located on a side of the first winding assembly along a first direction;
a transmission assembly connected to the first winding assembly and the lifting assembly, wherein the transmission assembly comprises a fastening member at least partially disposed in the accommodation chamber, the fastening member and the lifting assembly are located on a same side of the first winding assembly along the first direction; and
a display screen, wherein a first end of the display screen is connected to the first winding assembly, and a second end of the display screen is connected to the fastening member;
wherein the lifting assembly is located between the first end of the display screen and the second end of the display screen, the display device comprises a first state and a second state, and under the first state, the display screen is accommodated in the accommodation chamber;
wherein under the second state, the display screen is at least partially located outside the accommodation chamber, the transmission assembly controls the lifting assembly to move relative to the casing along the first direction and controls the first winding assembly rotate relative to the casing along a second direction to drive the display screen along the first direction to move relative to the casing, and the second direction intersects the first direction.

2. The display device according to claim 1, wherein the transmission assembly further comprises a first power member, the first power member controls the first winding assembly to rotate relative to the casing along the second direction, and the first power member comprises a first driver element disposed securely on the casing and a first connection element connected between the first driver element and the first winding assembly.

3. The display device according to claim 2, wherein
the first winding assembly comprises a first winding shaft member and a first rotation member, the first winding shaft member is rotatably connected to the casing, the first rotation member is disposed securely on at least one side of the first winding shaft member along a third direction, the third direction intersects the first direction and is parallel to an extension direction of the first winding shaft member; and
the first connection element is connected between the first driver element and the first rotation member.

4. The display device according to claim 3, wherein the display screen comprises a connection portion, the connection portion is located on a first end of the display screen, the connection portion is disposed securely on the first winding shaft member.

5. The display device according to claim 3, wherein the display device further comprises a second winding assembly at least partially disposed in the accommodation chamber, the second winding assembly comprises a second winding shaft member and a protection member, the second winding shaft member is rotatably connected to the casing, an extension direction of the second winding shaft member is parallel to the extension direction of the first winding shaft member, a first end of the protection member is disposed securely on the second winding shaft member, a second end of the protection member is disposed securely on the first winding shaft member, and under the first state, the protection member is located between adjacent two loops of the display screen.

6. The display device according to claim 1, wherein the lifting assembly comprises a lifting member, a side of the lifting member near the first winding assembly along the first direction is disposed securely on the casing, and under the second state, a side of the lifting member away from the first winding assembly along the first direction along the first direction moves relative to the casing.

7. The display device according to claim 6, wherein the lifting assembly further comprises a third winding shaft member, an extension direction of the third winding shaft member is parallel to an extension direction of a first winding shaft member of the first winding assembly, a portion of the third winding shaft member contacts a non-display surface of the display screen, and the non-display surface of the display screen is disposed opposite to a display surface of the display screen.

8. The display device according to claim 7, wherein a surface of the third winding shaft member comprises a plurality of protrusions and/or recesses arranged along the extension direction of the third winding shaft member.

9. The display device according to claim 6, wherein the lifting member comprises an expansion element and an expansion orientation element, and under the second state, the expansion orientation element controls the expansion element to expand or contract along the first direction.

10. The display device according to claim 6, wherein the transmission assembly further comprises second power member, the second power member is disposed securely on the casing, and under the second state, the second power member controls a side of the lifting member away from the first winding assembly along the first direction to move relative to the casing along the first direction.

11. The display device according to claim 1, wherein the fastening member comprises a fastening element, a rotation shaft element, and an elastic element, the second end of the display screen is disposed securely on the fastening element, the fastening element is disposed securely on the rotation shaft element, the rotation shaft element is rotatably connected to the casing, an extension direction of the rotation shaft element is parallel to an extension direction of the first winding shaft member of the first winding assembly, a first end of the elastic element is disposed securely on at least one side of the rotation shaft element along a third direction, and a second end of the elastic element is disposed securely on the casing.

12. The display device according to claim 11, wherein the display screen further comprises a display part and a first wiring board located on a second end of the display part, and the first wiring board is disposed securely on the fastening element.

13. The display device according to claim 1, wherein the display device further comprises a third state, under the third state, the first winding assembly does not rotate relative to the casing, and the transmission assembly controls the lifting assembly to keep a displacement relative to the casing along the first direction under the second state.

14. A display device, comprising:
a casing, wherein an accommodation chamber is defined in the casing;
a first winding assembly at least partially disposed in the accommodation chamber;
a lifting assembly at least partially disposed in the accommodation chamber, wherein the lifting assembly is located on a side of the first winding assembly along a first direction;
a transmission assembly connected to the first winding assembly and the lifting assembly, wherein the transmission assembly comprises a fastening member at least partially disposed in the accommodation chamber, the fastening member and the lifting assembly are located on a same side of the first winding assembly along the first direction; and
a display screen, wherein a first end of the display screen is connected to the first winding assembly, and a second end of the display screen is connected to the fastening member;
wherein the lifting assembly is located between the first end of the display screen and the second end of the display screen, the display device comprises a first state and a second state, and under the first state, the display screen is accommodated in the accommodation chamber;
wherein under the second state, the display screen is at least partially located outside the accommodation chamber, the transmission assembly controls the lifting assembly to move relative to the casing along the first direction and controls the first winding assembly rotate relative to the casing along a second direction to drive the display screen along the first direction to move relative to the casing, and the second direction intersects the first direction;
wherein the transmission assembly further comprises a first power member, the first power member controls the first winding assembly to rotate relative to the casing along the second direction, and the first power member comprises a first driver element disposed securely on the casing and a first connection element connected between the first driver element and the first winding assembly;
wherein the lifting assembly comprises a lifting member, a side of the lifting member near the first winding assembly along the first direction is disposed securely on the casing, and under the second state, a side of the lifting member away from the first winding assembly along the first direction along the first direction moves relative to the casing.

15. The display device according to claim 14, wherein
the first winding assembly comprises a first winding shaft member and a first rotation member, the first winding shaft member is rotatably connected to the casing, the first rotation member is disposed securely on at least one side of the first winding shaft member along a third direction, the third direction intersects the first direction and is parallel to an extension direction of the first winding shaft member; and
the first connection element is connected between the first driver element and the first rotation member.

16. The display device according to claim 15, wherein the display screen comprises a connection portion, the connection portion is located on a first end of the display screen, the connection portion is disposed securely on the first winding shaft member.

17. The display device according to claim 15, wherein the display device further comprises a second winding assembly at least partially disposed in the accommodation chamber, the second winding assembly comprises a second winding shaft member and a protection member, the second winding shaft member is rotatably connected to the casing, an extension direction of the second winding shaft member is parallel to the extension direction of the first winding shaft member, a first end of the protection member is disposed securely on the second winding shaft member, a second end of the protection member is disposed securely on the first winding shaft member, and under the first state, the protection member is located between adjacent two loops of the display screen.

18. The display device according to claim 14, wherein the lifting assembly further comprises a third winding shaft member, an extension direction of the third winding shaft member is parallel to an extension direction of a first winding shaft member of the first winding assembly, a portion of the third winding shaft member contacts a non-display surface of the display screen, and the non-display surface of the display screen is disposed opposite to a display surface of the display screen.

19. The display device according to claim 18, wherein a surface of the third winding shaft member comprises a plurality of protrusions and/or recesses arranged along the extension direction of the third winding shaft member.

20. The display device according to claim 14, wherein the lifting member comprises an expansion element and an expansion orientation element, and under the second state, the expansion orientation element controls the expansion element to expand or contract along the first direction.
